(19) United States
(12) Patent Application Publication
(10) Pub. No.: US 2010/0329388 A1
(43) Pub. Date: Dec. 30, 2010

(54) FREQUENCY SYNTHESIZER AND POLAR TRANSMITTER HAVING THE SAME

(76) Inventor: Sang-Soo KO, Suwon-si (KR)

Correspondence Address: F. CHAU & ASSOCIATES, LLC, 130 WOODBURY ROAD, WOODBURY, NY, 11797, US

(21) Appl. No.: 12/761,451

(22) Filed: Apr. 16, 2010

(30) Foreign Application Priority Data
Jun. 29, 2009 (KR) 10-2009-0058018

(51) Int. Cl. H04L 27/36; H03L 7/087

(52) U.S. Cl. 375/300; 331/1 A

(57) ABSTRACT

A frequency synthesizer includes a distributed phase detector circuit, a multiple charge pump, a loop filter, a voltage-controlled oscillator and a dividing circuit. The distributed phase detector circuit delays an up signal and a down signal to generate a delayed up signal and a delayed down signal. The multiple charge pump generates a distributed current signal including a plurality of current pulse signals. Each of the current pulse signal is based on each bit of the delayed up signal and the delayed down signal. The loop filter filters the distributed current signal to generate a control voltage. The voltage-controlled oscillator generates an oscillation frequency signal based on the control voltage. The dividing circuit divides the oscillation frequency signal to generate a plurality of division frequency signals in response to a plurality of control signals, where the frequency signals are fedback to the distributed phase detector circuit.

### CROSS-REFERENCE TO RELATED APPLICATIONS

This application claims priority under 35 USC §119 to Korean Patent Application No. 2009-0058018, filed on Jun. 29, 2009 in the Korean Intellectual Property Office (KIPO), the disclosure of which is incorporated by reference in its entirety herein.

### BACKGROUND

1. Technical Field

Exemplary embodiments of the inventive concept relate to frequency synthesizing, and more particularly to a frequency synthezier and a polar transmitter having the same.

2. Discussion of Related Art

A phase-locked loop (PLL) is a closed-loop frequency-control system based on the phase difference between an input signal and a feedback signal of a controlled oscillator. PLL circuits may be used to synthesize a desired signal frequency. A frequency synthesizer of a PLL may employ an integer-N technique and a fractional-N technique. The integer-N technique uses a fixed integer N to divide an output frequency. The fractional-N technique uses a number N to divide the output frequency, which is selected from among two or more integers (e.g., N is varied between two or more integers such that the average value of N is fractional). As a result, a divisor is fractional when using the fractional-N technique due to interpolation of each number N selected for each dividing operation.

However, it may be difficult to meet certain specifications when employing the integer-N technique due to a trade-off between loop bandwidth and channel spacing. The fractional-N technique alleviates such design restrictions on PLLs, thereby permitting a broader loop bandwidth while maintaining narrow channel intervals.

However, the fractional-N technique results in the generation of fractional spurious signals (i.e., spurs). A frequency synthesizer incorporating a sigma/delta modulator may be employed to reduce the occurrence of fractional spurs. However, frequency synthesizers incorporating sigma/delta modulators suffer from sigma/delta noise (e.g., a quantization noise).

### SUMMARY

According to an exemplary embodiment of the inventive concept, a frequency synthesizer includes a distributed phase detector circuit, a multiple charge pump, a loop filter, a voltage-controlled oscillator and a dividing circuit. The distributed phase detector circuit delays an up signal and a down signal to generate a delayed up signal and a delayed down signal. The up signal and the down signal are based on a reference frequency signal and each of a plurality of division frequency signals. The up signal and the down signal have a plurality of bits respectively. The multiple charge pump is configured to generate a distributed current signal including a plurality of current pulse signals. Each current pulse signal is based on each bit of the delayed up signal and the delayed down signal. The loop filter filters the distributed current signal to generate a control voltage. The dividing circuit divides the oscillation frequency signal to generate the plurality of division frequency signals in response to a plurality of control signals.

The frequency synthesizer may further include a sigma-delta modulator (SDM) that operates in synchronization with one of the plurality of division frequency signals, and sigma-delta modulates a clock signal and data to generate a modulation signal and a first delay unit that delays the modulation signal to generate the control signals for output to the dividing circuit.

The distributed phase detector circuit may include a multiple phase detector that generates the up signal and the down signal based on respective frequency differences between the reference frequency signal and each of the plurality of division frequency signals and a second delay unit that delays each bit of the up signal the down signal by different delays with respect to one another to generate the delayed up signal and the delayed down signal.

The second delay unit may include a plurality of delay cells and each of the cells delays each bit of the up signal and the down signal by different delays with respect to one another in one period of the reference frequency signal. Each of the different delays may increase as time elapses in one period of the reference frequency signal. Alternately, each of the different delays may decrease as time elapses in one period of the reference frequency signal.

The dividing circuit may include a prescaler that generates a plurality of intermediate frequency signals having a same phase difference with respect to one another in response to the oscillation frequency signal, and a plurality of modulus dividers commonly coupled to the prescaler, which respectively divide the plurality of intermediate frequency signals by respective ratios to generate the plurality of division frequency signals in response to the control signals.

Each of the plurality of modulus dividers may include a phase selection unit that selects one of the plurality of intermediate frequency signals to generate a selection frequency signal in response to a phase control signal, a first divider that divides the selection frequency signal with a fixed first division ratio to generate a divided selection frequency signal, a counting unit that counts the divided selection frequency signal to generate the division frequency signal and divide a counting interval of the divided selection frequency signal to generate a modulus control signal, and a logic gate that generates the phase control signal based on the modulus control signal and the divided selection frequency signal.

The phase selection unit includes a phase controller that generates a frequency control signal in response to the phase selection signal and a phase switch that switches and selects one of the plurality of intermediate frequency signals in response to the frequency selection signal.

The counting unit may include a main counter that counts the divided selection frequency signal to generate a counting result as the division frequency signal in response to the control signal, a swallow counter that divides a counting interval of the divided selection frequency signal and counts the counting interval with different counting coefficients to generate the modulus control signal, and the swallow counter that may be reset by the division frequency signal.

The SDM may be one of fourth-order or fifth-order. The fourth-order SDM may include first, second, third, and fourth delayers, first, second, third, fourth, fifth, and sixth adders, first, second, third, and fourth feedback coefficient multipliers, and a quantizer. The first adder, second adder, first delayer, third adder, second delayer, fourth adder, third delayer, fifth adder, fourth delayer, fourth feedback coefficient multiplier, sixth adder, and quantizer are respectively and consecutively connected in series. The first adder adds the corresponding one division frequency signal to an output of the quantizer. The second adder adds an output of the first adder to an output of the first feedback coefficient multiplier. The third adder adds an output of the first delayer and an output of the second feedback coefficient multiplier. The fourth adder adds an output of the second delayer and an output of the third feedback coefficient multiplier. The fifth adder adds an output of the third delayer and an output of the fourth feedback coefficient multiplier. The sixth adder adds others outputs of the first, second, third, and fourth feedback coefficient multipliers. The first, second, third, and fourth feedback coefficient multipliers respectively may have coefficients of 3, 3.5, 2, and 0.5.

The fifth-order SDM may include first, second, third, fourth, and fifth delayer, first, second, third, fourth, fifth, sixth, and seventh adders, first, second, third, fourth, and fifth feedback coefficient multipliers, and a quantizer. The first adder, second adder, first delayer, third adder, second delayer, fourth adder, third delayer, fifth adder, fourth delayer, sixth adder, fifth delayer, fifth feedback coefficient multiplier, seventh adder, and quantizer are respectively and consecutively connected in series. The first adder adds the corresponding one division frequency signal to an output of the quantizer. The second adder adds an output of the first adder to an output of the first feedback coefficient multiplier. The third adder adds an output of the first delayer and an output of the second feedback coefficient multiplier. The fourth adder adds an output of the second delayer and an output of the third feedback coefficient multiplier. The fifth adder adds an output of the third delayer and an output of the fourth feedback coefficient multiplier. The sixth adder adds an output of the fourth delayer and an output of the fifth feedback coefficient multiplier. The seventh adder adds others outputs of the first, second, third, fourth feedback, and fifth feedback coefficient multipliers. The first, second, third, fourth, and fifth feedback coefficient multipliers may respectively have coefficients of 4, 6.5, 5.5, 2.5, and 0.5.

According to an exemplary embodiment of the inventive concept, a frequency synthesizer includes a multiple phase detector, a multiple charge pump, a loop filter, a voltage-controlled oscillator, a dividing circuit and a phase control unit. The multiple phase detector generates an up signal and a down signal in response to a reference frequency signal and each of a plurality of phase division frequency signals, and the up signal and the down signal have a plurality of bits respectively. The multiple charge pump generates a current signal including a plurality of current pulse signals, each of which is based on each bit of the up signal and the down signal. The loop filter filters the current signal to generate a control voltage. The voltage-controlled oscillator generates an oscillation frequency signal based on the control voltage. The dividing circuit divides the oscillation frequency signal to generate the plurality of division frequency signals in response to a plurality of control signals. The phase control unit divides the reference frequency signal into a first plurality of frequency signals having a same phase difference with respect to one another, divides each of the division frequency signals into a second plurality of frequency signals to generate in-phase frequency signals as the phase division frequency signals, and each of the in-phase frequency signals has the same phase as one of the first plurality of frequency signals and one of the second plurality of frequency signals.

The phase control unit may include a first divider that generates the first plurality of frequency signals based on the reference frequency signal and a second plurality of dividers that generate the second plurality of frequency signals based on the division frequency signals.

The multiple phase detector may include a plurality of phase detectors, and each of the phase detectors detects a phase difference between each of the first plurality of frequency signals and each of the plurality of phase division frequency signals.

According to an exemplary embodiment of the inventive concept, a polar transmitter includes a data processing unit, a frequency synthesizer and a power amplifier. The data processing unit processes baseband data and converts the processed baseband data to an amplitude signal and a phase signal. The frequency synthesizer generates an oscillation frequency signal based on a reference frequency signal and the phase signal. The power amplifier synthesizes the oscillation frequency signal and the amplitude signal to output a transmission signal. The frequency synthesizer generates the oscillation frequency signal based on the reference frequency signal and each of a plurality of division frequency signals, and the frequency synthesizer includes a distributed phase detector circuit that distributes an up signal and a down signal for preventing the up signal and the down signal from overlapping. The up signal and the down signal are based on a respective phase difference between the reference frequency signal and each of the plurality of division frequency signals. The data processing unit may be a Coordinate Rotational Digital Computer.

### BRIEF DESCRIPTION OF THE DRAWINGS

Exemplary embodiments of the inventive concept will be more clearly understood from the following detailed description taken in conjunction with the accompanying drawings.

FIG. 1 is a block diagram illustrating a frequency synthesizer according to an exemplary embodiment of the inventive concept.

FIG. 2 illustrates an exemplary connection relationship between phase detectors, delay cells and charge pumps in FIG. 1.

FIGS. 3A and 3B illustrate exemplary embodiments of each delay of the delay cells in FIG. 2.

FIG. 4A illustrates a plurality of exemplary current pulse signals and an exemplary current signal when an up signal and a down signal are not delayed.

FIGS. 4B and 4C illustrate a plurality of exemplary current pulse signals and an exemplary distributed current signal according to time.

FIG. 5 is a block diagram illustrating an example of a dividing circuit in FIG. 1 according to an exemplary embodiment of the inventive concept.

FIG. 6 is a block diagram illustrating a modulus divider in FIG. 5 according to an exemplary embodiment of the inventive concept.

FIG. 7 is a block diagram illustrating a delay unit in FIG. 1 according to an exemplary embodiment of the inventive concept.

FIG. 8 is a block diagram illustrating a delay register in FIG. 7 according to an exemplary embodiment of the inventive concept.

FIG. 9 illustrates a fourth-order sigma-delta modulator (SDM) that may be used as the SDM of FIG. 1 according to an exemplary embodiment of the inventive concept.

FIG. 10 illustrates a fifth-order sigma-delta modulator that may be used as the SDM of FIG. 1 according to an exemplary embodiment of the inventive concept.

FIG. 11 is a block diagram illustrating a frequency synthesizer according to an exemplary embodiment of the inventive concept.

FIG. 12 is a block diagram illustrating an example of a phase control unit in FIG. 11 according to an exemplary embodiment of the inventive concept.

FIG. 13 is a block diagram illustrating an application circuit incorporating a frequency synthesizer according to an exemplary embodiment of the inventive concept.

### DETAILED DESCRIPTION OF EXEMPLARY EMBODIMENTS

Exemplary embodiments of the inventive concept will be described more fully hereinafter with reference to the accompanying drawings. The present inventive concept may, however, be embodied in many different forms and should not be construed as limited to the exemplary embodiments set forth herein. In the drawings, like numerals refer to like elements throughout.

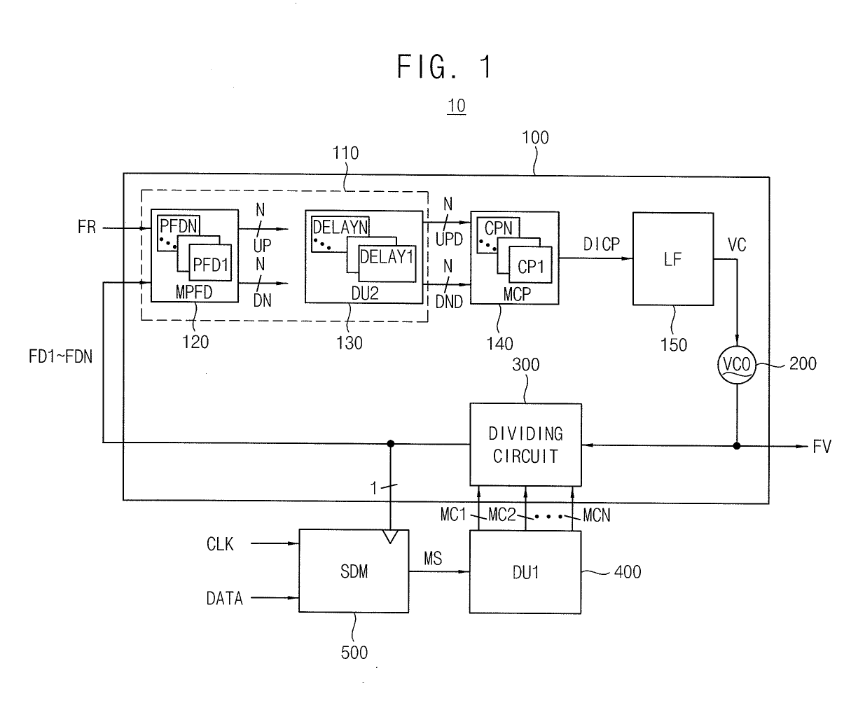

FIG. 1 is a block diagram illustrating a frequency synthesizer according to an exemplary embodiment of the inventive concept. Referring to FIG. 1, a frequency synthesizer 10 includes a phase-locked loop (PLL) 100, a first delay unit 400, and a sigma-delta modulator (SDM) 500.

The PLL 100 includes distributed phase detector circuit 110, a multiple charge pump 140, a loop filter 150, a voltage-controlled oscillator (VCO) 200 and a dividing circuit 300. The distributed phase detector circuit 110 includes a multiple phase detector 120 and a second delay unit 130.

The multiple phase detector 120 includes a plurality of phase detectors PFD1˜PFDN, and compares a reference frequency signal FR with each of a plurality of division frequency signals FD1˜FDN, to generate a plurality of bits of an up signal UP and a plurality of bits of a down signal DN based on respective phase differences between the reference frequency signal FR and each of the division frequency signals FD1˜FDN. The up signal UP and the down signal DN may be N bits respectively, where N is a positive integer.

The second delay unit 130 includes a plurality of delay cells DELAY1˜DELAYN, and each of the delay cells DELAY1˜DELAYN delays each bit of the up signal UP and each bit of the down signal DN by different delays with respect to each other, to generate bits of a delayed up signal UPD and bits of a delayed down signal DND. The delayed up signal UPD and the delayed down signal DND may be N bits respectively, where N is a positive integer equal to or greater than one.

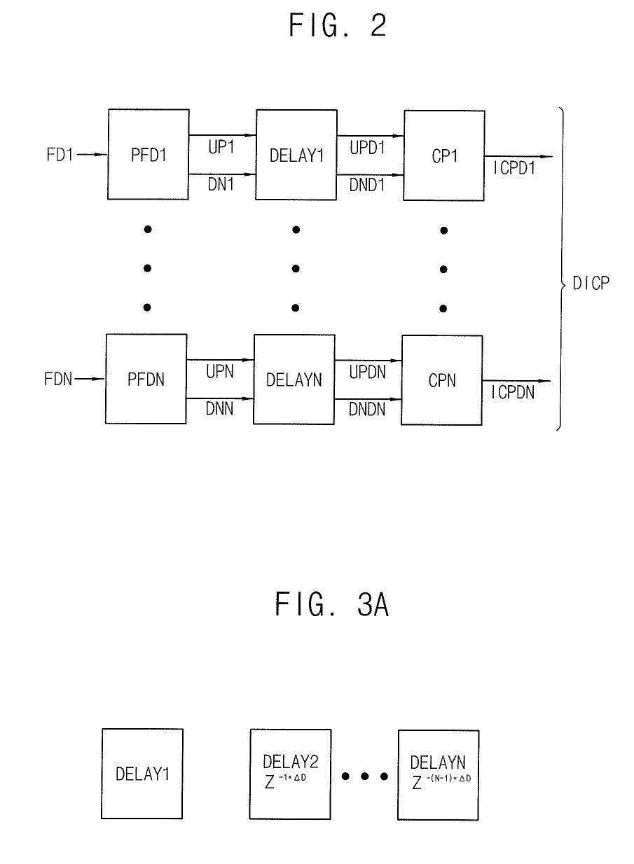

The multiple charge pump 140 includes a plurality of charge pumps CP1˜CPN, and each of the charge pumps CP1˜CPN may receive each bit of the delayed up signal UPD and the delayed down signal DND to generate each of a plurality of current pulse signals ICPD1˜ICPDN (refer to FIG. 2). For example, the multiple charge pump 140 generates a distributed current pulse signal DICP including the plurality of current pulse signals ICPD1˜ICPDN based on the delayed up signal UPD and the delayed down signal DND.

The loop filter 150 filters the distributed current pulse signal DICP to generate a control voltage VC. The VCO 200 generates an oscillation frequency signal FV based on the control voltage VC. For example, the VCO 200 generates the oscillation frequency signal FV proportional to the control voltage VC. The oscillation frequency signal FV may be a single-ended signal or may include differential signals.

The dividing circuit 300 receives the oscillation frequency signal FV, and divides the oscillation frequency signal FV with respective division ratios based on control signals MC1˜MCN to generate the division frequency signals FD1˜FDN. The VCO 200 may be an LC oscillator.

The SDM 500 operates in synchronization with one of the division frequency signals FD1˜FDN, and sigma-delta modulates a clock signal CLK and data DATA to generate a modulation signal MS.

The first delay unit 400 delays the modulation signal MS N times to generate a plurality of control signals MC1˜MCN, and applies the generated control signals MC1˜MCN to the dividing circuit 300.

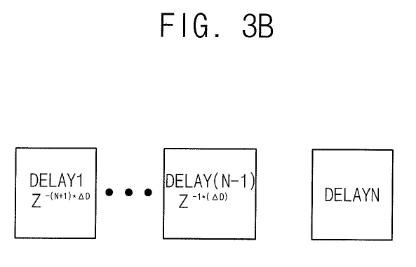

FIG. 2 illustrates an exemplary connection relationship between the phase detectors, the delay cells and the charge pumps in FIG. 1. FIGS. 3A and 3B illustrate each delay of the delay cells in FIG. 2.

Referring to FIGS. 2 through 3B, each of the phase detectors PFD1˜PFDN is connected to each of the delay cells DELAY1˜DELAYN, and each of the delay cells DELAY1˜DELAYN is connected to each of the charge pumps CP1˜CPN. In addition, each of the delay cells DELAY1˜DELAYN may gradually increase delays with respect to each other, or of the delay cells DELAY1˜DELAYN may gradually decrease delays with respect to each other. For example, FIG. 3A illustrates an example where each of the delay cells DELAY1˜DELAYN gradually increase delays with respect to each other, and FIG. 3B illustrates an example where each of the delay cells DELAY1˜DELAYN gradually decrease delays with respect to each other.

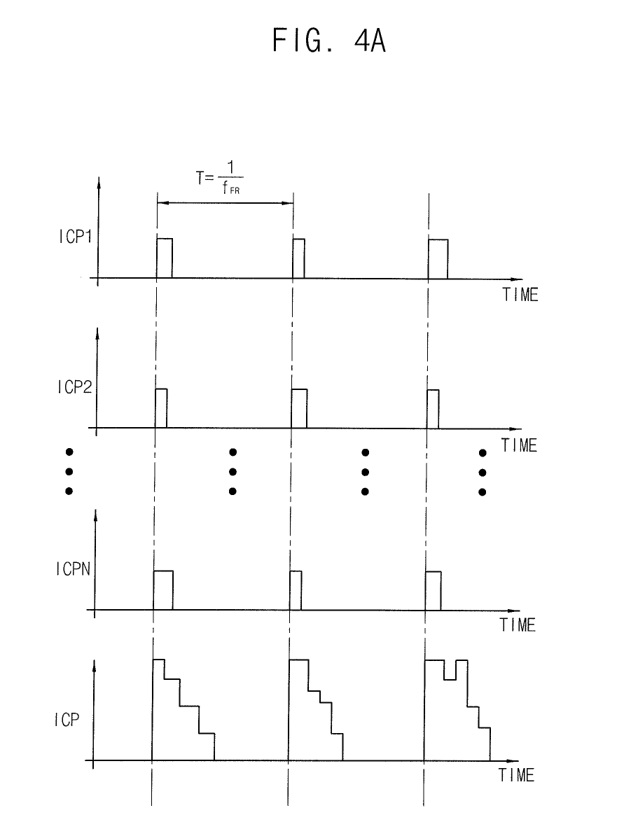

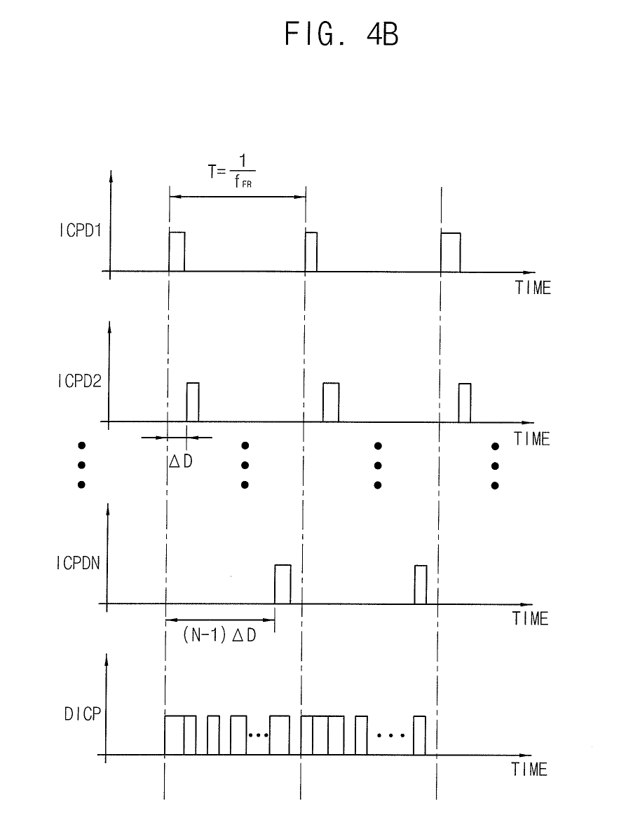

FIG. 4A illustrates a plurality of exemplary current pulse signals and an exemplary current signal when the up signal and the down signal are not delayed. For example, FIG. 4A illustrates an output signal of the multiple charge pump 140 in FIG. 1 when the second delay unit 130 is not included in the distributed phase detector circuit 110 in FIG. 1.

Referring to FIG. 4A, a current signal ICP is the summation of a plurality of current pulse signal ICP1˜ICPN. When the current signal ICP is directly input to the loop filter 150, the loop filter 150 low-pass filters the current signal ICP. However, a high-frequency component of the current signal ICP may not be completely removed, because the current signal ICP is the summation of the plurality of current pulse signal ICP1˜ICPN. Therefore, the control voltage VC (i.e., the output of the loop filter 150) may have some ripples due to the high-frequency component of the current signal ICP. Harmonic spurious signals (i.e., spurs) may be generated due to the ripples, thereby increasing sigma-delta modulation noise.

FIGS. 4B and 4C illustrate a plurality of exemplary current pulse signals and an exemplary distributed current signal according to time. For example, FIGS. 4B and 4C illustrate an output signal of the multiple charge pump 140 in FIG. 1 when the second delay unit 130 is included in the distributed phase detector circuit 110 in FIG. 1.

Referring to FIGS. 4B and 4C, the plurality of current pulse signals ICDP1˜ICDPN are output with delays with respect to each other such that each of the current pulse signals ICDP1˜ICDPN is not overlapped with respect to each other in one period 1/f_{FR} of the reference frequency signal FR. Therefore, the distributed current signal DICP, which is the summation of the current pulse signals ICDP1˜ICDPN may have few overlapping parts of the current pulse signals ICDP1˜ICDPN. Therefore, when the distributed current signal DICP is input to the loop filter 150, a high-frequency component of the distributed current signal DICP may be almost completely removed. Therefore, the control voltage VC (i.e., the output of the loop filter 150) may have no ripples. Therefore, spurs may not be generated, thereby reducing the sigma-delta modulation noise.

FIG. 4B illustrates that each delay (Δ*D˜Δ*(N−1)*D) of the current pulse signals ICDP1˜ICDPN increases with respect to each other as time elapses in one period 1/f_{FR} of the reference frequency signal FR. FIG. 4C illustrates that each delay (Δ*(N−1)*D˜Δ*D) of the current pulse signals ICDP1˜ICDPN decreases with respect to each other as time elapses in one period 1/f_{FR} of the reference frequency signal FR. Therefore, the current pulse signals ICDP1˜ICDPN may have few overlapping parts with respect to each other by adjusting each delay of the delay cells DELAY1˜DELAYN.

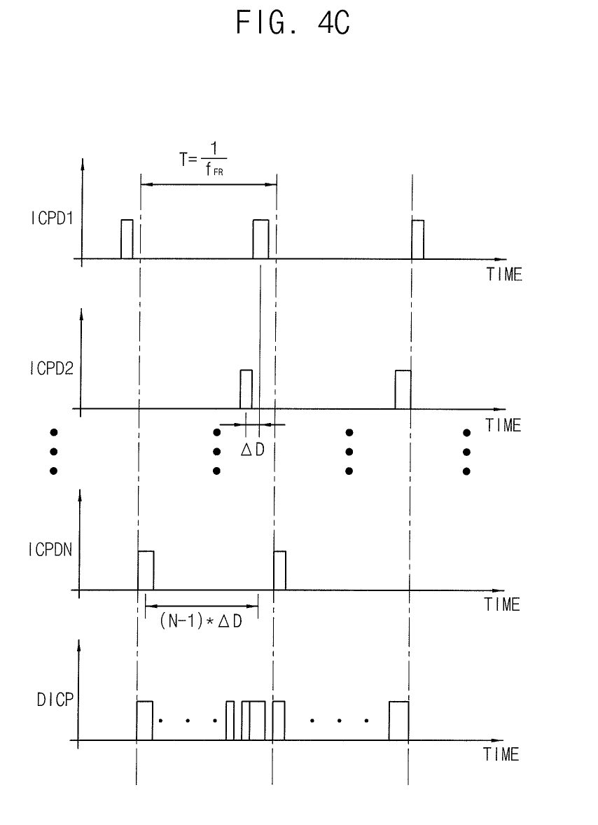

FIG. 5 is a block diagram illustrating an example of the dividing circuit 300 in FIG. 1 according to an exemplary embodiment of the inventive concept. Referring to FIG. 1, the dividing circuit 300 includes a prescaler 310 and a plurality of modulus dividers 320.

The prescaler 310 may be implemented with a divider having a fixed division ratio, e.g., four. The prescaler 310 generates a plurality of intermediate frequency signals, for example four intermediate frequency signals F0, F90, F180, and F270 in response to an oscillation frequency signal FV. The oscillation frequency signal FV may be a single-ended signal or include differential signals. In addition, the oscillation frequency signal FV may be represent a first logic level signal.

The intermediate frequency signals F0, F90, F180, and F270 have a same phase difference with respect to one another and may represent second logic level signals. For example, the intermediate frequency signals F0, F90, F180, and F270 may have phase differences of 90 degrees with respect to one another. The first logic level may be current-mode logic (CML) level, and the second logic level may be a CMOS logic level.

The modulus dividers 320 are commonly coupled to the prescaler 100, and the modulus dividers 320 respectively divide the intermediate frequency signals F0, F90, F180, and F270 with respective ratios to generate a plurality of division frequency signals FD1, FD2, . . . , FDN in response to a control signal MC.

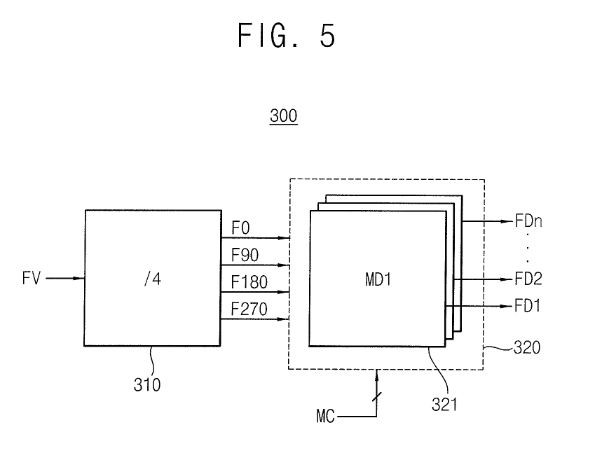

FIG. 6 is a block diagram illustrating one of the modulus dividers in FIG. 5 according to an exemplary embodiment of the inventive concept. In FIG. 6 a modulus divider 321 or MD1 of the modulus dividers 320 is illustrated.

Referring to FIG. 6, a modulus divider 321 includes a phase selection unit 230, a first divider 232, a counting unit 240 and a logic gate 234. The phase selection unit 230 includes a phase controller 231 and a phase switch 233. The counting unit 240 includes a main counter 241, and a swallow counter 242.

The phase selection unit 230 selects one of the intermediate frequency signals F0, F90, F180, and F270 to generate a selection frequency signal FS, in response to a phase control signal PCS. The phase switch 231 switches and selects one of the intermediate frequency signals F0, F90, F180, and F270, in response to a frequency selection signal FSS. The first divider 232 divides the selection frequency signal FS with a fixed division ratio to generate a divided selection frequency signal FSD. While FIG. 6 illustrates that the fixed division ratio is 16, this is merely an example, as the fixed division ratio may be set to a lessor or greater amount.

The counting unit 240 counts the divided selection frequency signal FSD to generate the division frequency signal FD1 and divides a counting interval of the divided selection frequency signal FSD to generate a modulus control signal MCS. The main counter counts the divided selection frequency signal FSD to generate the counting result as the division frequency signal FD1, in response to the control signal MC.

The swallow counter 242 divides the counting interval of the divided selection frequency signal FSD and counts the counting interval with different counting coefficients to generate the modulus control signal MCS, and the swallow counter 242 is reset by the division frequency signal FD1. The logic gate 231 performs a NAND operation on the modulus control signal MCS and the divided selection frequency signal FSD to generate the phase control signal PCS. As illustrated in FIG. 5, a plurality of modulus dividers such as the modulus divider 321 of FIG. 6 is commonly coupled to the prescaler 310 of FIG. 5.

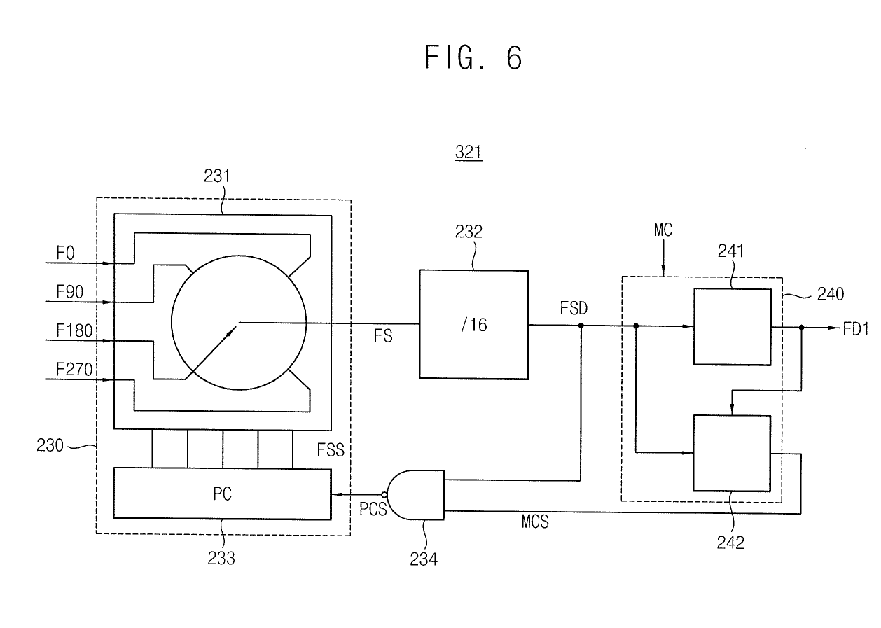

FIG. 7 is a block diagram illustrating a delay unit (e.g., 400) in FIG. 1 according to an exemplary embodiment of the inventive concept. Referring to FIG. 7, the delay unit 400 includes a delay register 410 and a resynchronizer 420. In an alternate embodiment, the delay unit 400 includes only the delay register 410.

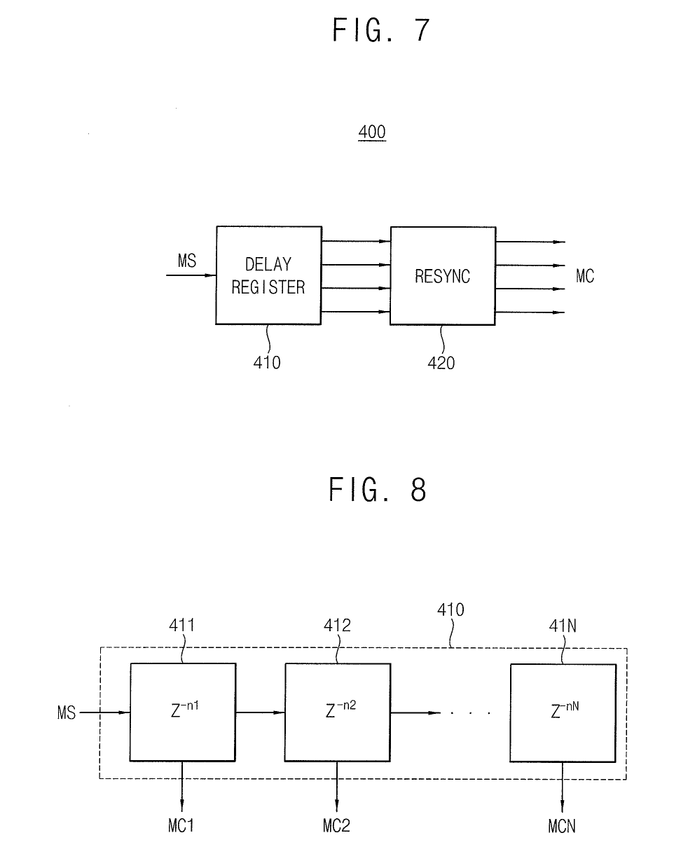

As will be described with reference to FIG. 8, the delay register 410 delays the modulation signal MS to generate N control signals MC1˜MCN. The N control signals MC1˜MCN have different delay times with respect to one another. The N control signals MC1˜MCN are applied to the modulus dividers 320 in FIG. 5. The delay register 410 may include a plurality of delay cells coupled in series or in parallel.

FIG. 8 is a block diagram illustrating the delay register 410 in FIG. 7 according to an exemplary embodiment of the inventive concept. Referring to FIG. 8, the delay register 410 include a plurality of delay cells 411, 412, . . . , 41N that are coupled in series. The delay cell 411 receives the modulation signal MS, and delays the modulation signal MS. The delay cells 411, 412, . . . , 41N that are coupled in series delay respective inputs. The delay cells 411, 412, . . . , 41N respectively generate the control signals MC1, MV2, . . . , MCN for output to the dividing circuit 300. The high frequency components of a quantization noise (e.g., resultingfrom sigma-delta modulation) included within the modulation signal MS are averaged while the control signals MC1˜MCN go through the PLL 100. For example, the delay register 410 may lower the level of quantization noise.

When the delay unit 400 further includes the resynchronizer 420, the resynchronizer 420 resynchronizes outputs of the delay register 410 to generate the control signals MC1˜MCN. In an exemplary embodiment as illustrated in FIG. 8, the delay register 410 includes series coupled delay cells 411, 412, . . . , 41N. In an alternate embodiment, the delay register 410 includes similar delay cells coupled in parallel.

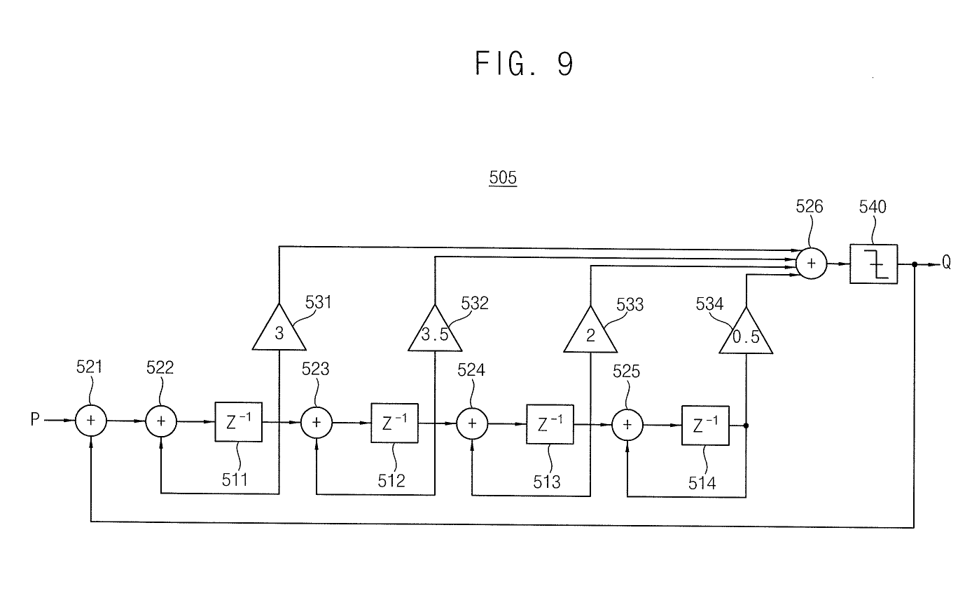

FIG. 9 illustrates a fourth-order sigma-delta modulator that may be employed by the SDM 500 of FIG. 1 according to an exemplary embodiment of the inventive concept. Referring to FIG. 9, a fourth-order sigma-delta modulator 505 includes delayers 511, 512, 513, and 514, adders 521, 522, 523, 524, 525, and 526, feedback coefficient multipliers 531, 532, 533, and 534 and a quantizer 540. For example, when input data includes 20 bits, the fourth-order sigma-delta modulator 505 may generate output of 7 levels. However, 20 bit input data is merely an example, as the input data may include a lessor or greater number of bits. While FIG. 9 illustrates coefficient multipliers of 3, 3.5, 2, and 0.5, embodiments of the present inventive concept are not limited thereto, as the coefficient multipliers may be changed as needed.

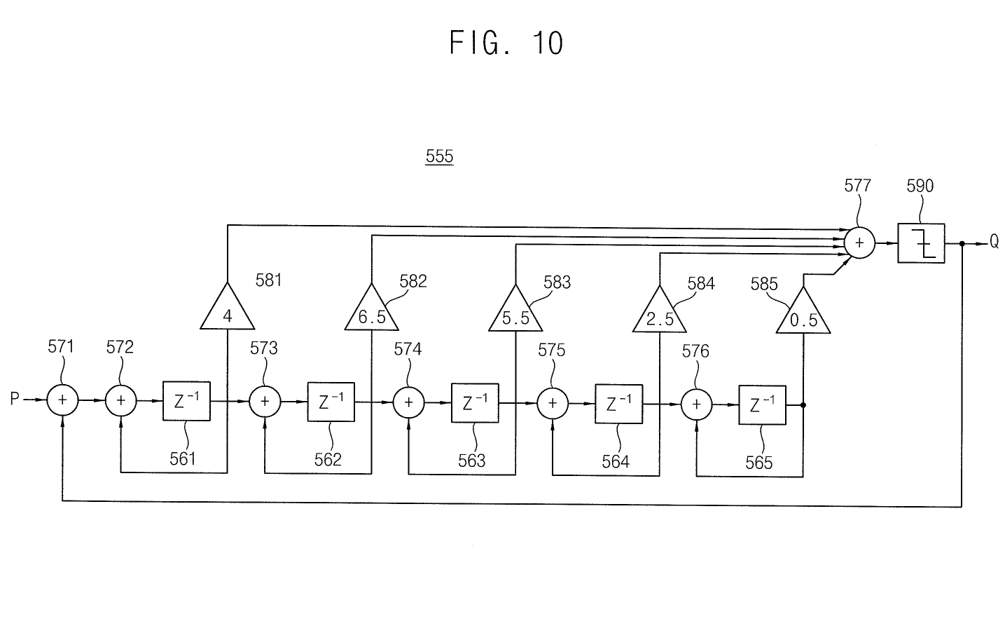

FIG. 10 illustrates a fifth-order sigma-delta modulator that may be employed by the SDM 500 of FIG. 1 according to an exemplary embodiment of the inventive concept. Referring to FIG. 10, a fifth-order sigma-delta modulator 555 includes delayers 561, 562, 563, 564, and 565, adders 571, 572, 573, 574, 575, 576, and 577 feedback coefficient multipliers 581, 582, 583, 584, 585 and a quantizer 590. When input data includes 20 bits, the fifth-order sigma-delta modulator 555 may generate an output of 20 levels. However, 20 bit input data is merely an example, as the input data may include a lessor or greater number of bits. While FIG. 10 illustrates coefficient multipliers of 4, 6.5, 5.5, 2.5, and 0.5, embodiments of the present inventive concept are not limited thereto, as the coefficient multipliers may be changed as needed.

Although not illustrated in FIG. 9 or FIG. 10, one tap of a digital FIR filter (1+z⁻¹) may be coupled to the output of the sigma-delta modulator of FIGS. 9 and 10 (e.g., 505 or 555) for comparing performance. When the fourth-order or fifth-order sigma-delta modulator 505 or 55 is employed, the quantization noise may be shifted from a lower frequency area to a higher frequency area, and thus noise characteristics may be enhanced.

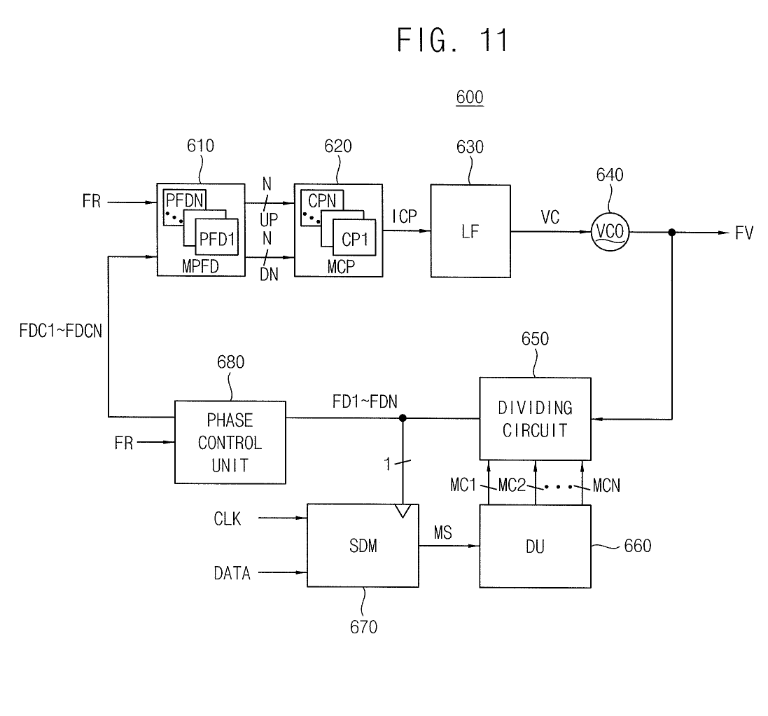

FIG. 11 is a block diagram illustrating a frequency synthesizer according to an exemplary embodiment of the inventive concept. Referring to FIG. 11, a frequency synthesizer 600 includes a multiple phase detector 610, a multiple charge pump 620, a loop filter 630, a voltage-controlled oscillator (VCO) 640, a dividing circuit 650, a delay unit 660, a sigma-delta modulator (SDM) 670 and a phase control unit 680.

The multiple phase detector 610 includes a plurality of phase detectors PFD1˜PFDN, and compares the reference frequency signal FR and each of phase division frequency signals FDC1˜FDCN, to generate a plurality of bits of an up signal UP and a plurality of bits of a down signal DN based on a respective phase difference between the reference frequency signal FR and each of the phase division frequency signals FDC1˜FDCN. The up signal UP and the down signal DN may be N bits respectively, where N is a positive integer equal or greater than 1.

The multiple charge pump 620 includes a plurality of charge pumps CP1˜CPN, and each of the charge pumps CP1˜CPN may receive each bit of the up signal UP and the down signal DN to generate each of a plurality of current pulse signals ICP1˜ICPN (refer to FIG. 2). For example, the multiple charge pump 620 generates a current signal ICP including the plurality of current pulse signals ICP1˜ICPN based on of the up signal UP and the down signal DN.

The loop filter 630 filters the current signal ICP to generate a control voltage VC. The VCO 640 generates the oscillation frequency signal FV based on the control voltage VC. For example, the VCO 640 generates the oscillation frequency signal FV proportional to the control voltage VC. The oscillation frequency signal FV may be a single-ended signal or may include differential signals.

The dividing circuit 650 receives the oscillation frequency signal FV, and divides the oscillation frequency signal FV with respective division ratios based on the control signals MC1˜MCN to generate the division frequency signals FD1˜FDN. The VCO 640 may be an LC oscillator.

The SDM 670 operates in synchronization with one of the division frequency signals FD1˜FDN, and sigma-delta modulates a clock signal CLK and data DATA to generate a modulation signal MS.

The first delay unit 660 delays the modulation signal MS N times to generate a plurality of control signals MC1˜MCN, and applies the generated control signals MC1˜MCN to the dividing circuit 650.

The phase control unit 680 receives the division frequency signals FD1˜FDN and the reference frequency signal FR and generates the phase division frequency signals FDC1˜FDCN.

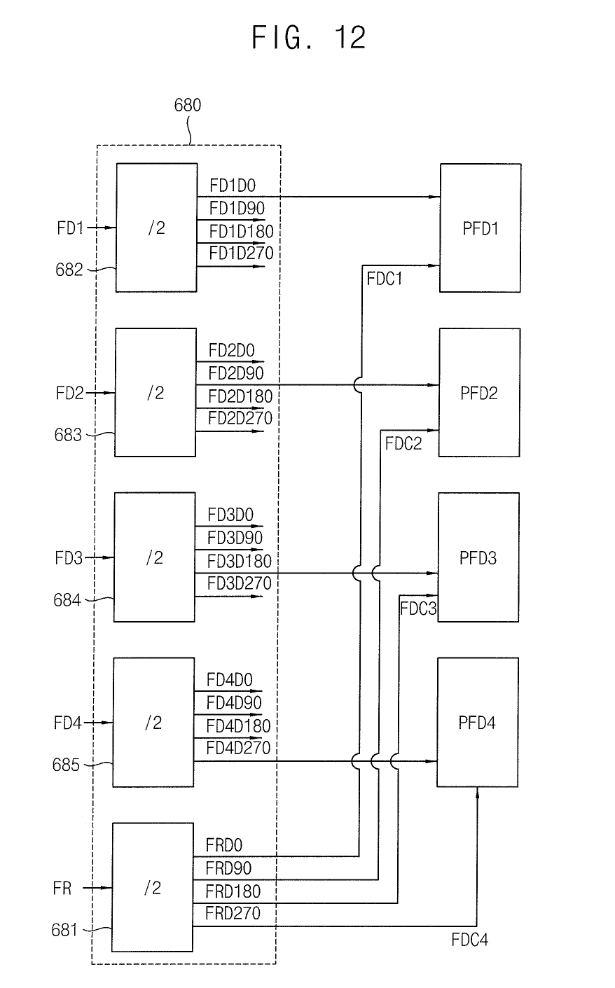

FIG. 12 is a block diagram illustrating an example of the phase control unit 680 in FIG. 11 according to an exemplary embodiment of the inventive concept. In FIG. 12, four phase detectors PFD1˜PFD4 are illustrated.

Referring to FIG. 12, the phase control unit includes a first divider 681 and a plurality of second dividers 682, 683, 684 and 685. While FIG. 12 shows each of the dividers 681˜685 having a division ratio of two, embodiments of the inventive concept are not limited thereto. In an exemplary an exemplary embodiment of the inventive concept, the variable N in FIG. 11 corresponds to four, and the division frequency signals FD1˜FDN and the reference frequency signal FR are differential signals.

The first divider 681 divides the reference frequency signal FR with a division ratio of two to generate a first plurality of frequency signals FRD0, FRD90, FRD180, and FRD270 having a same phase difference with respect to one another. For example, the first frequency signals FRD0, FRD90, FRD180, and FRD270 may have a phase differences of 90 degrees with respect to one another.

The divider 682 divides the division frequency signal FD1 by a division ratio of two to generate a second plurality of frequency signals FD1D0, FD1D90, FD1D180, and FD1D270 having a same phase difference with respect to one another. For example, the second frequency signals FD1D0, FD1D90, FD1D180, and FD1D270 may have a phase difference of 90 degrees with respect to one another.

The divider 683 divides the division frequency signal FD2 by a division ratio of two to generate a second plurality of frequency signals FD2D0, FD2D90, FD2D180, and FD2D270 having a same phase difference with respect to one another. For example, the second frequency signals FD2D0, FD2D90, FD2D180, and FD2D270 may have a phase difference of 90 degrees with respect to one another.

The divider 684 divides the division frequency signal FD3 by a division ratio of two to generate a second plurality of frequency signals FD3D0, FD3D90, FD3D180, and FD3D270 having same phase difference with respect to one another. The second frequency signals FD3D0, FD3D90, FD3D180, and FD3D270 may have a phase difference of 90 degrees with respect to one another.

The divider 685 divides the division frequency signal FD4 by a division ratio of two to generate a second plurality of frequency signals FD4D0, FD4D90, FD4D180, and FD4D270 having a same phase difference with respect to one another. For example, the second frequency signals FD4D0, FD4D90, FD4D180, and FD4D270 may have a phase difference of 90 degrees with respect to one another.

The first divider 681 generates each of the first plurality of frequency signals FRD0, FRD90, FRD180, and FRD270 for output to each of the phase detectors PFD1˜PFD4, respectively. For example, the frequency signal FRD0 is output to the phase detector PFD1, the frequency signal FRD90 is output to the phase detector PFD2, the frequency signal FRD180 is output to the phase detector PFD3, and the frequency signal FRD270 is output to the phase detector PFD4. In addition, the frequency signal FD1D0 is output to the phase detector PFD1, the frequency signal FD2D90 is output to the phase detector PFD2, the frequency signal FD3D180 is output to the phase detector PFD3, and the frequency signal FD4D270 is output to the phase detector PFD4.

Therefore, the phase detector PFD1 can detect a difference between the frequency signals FRD0 and FD1D0, the phase detector PFD2 can detect a difference between the frequency signals FRD90 and FD2D90, the phase detector PFD3 can detect a difference between the frequency signals FRD180 and FD3D180, and the phase detector PFD4 can detect a difference between the frequency signals FRD270 and FD4D270.

For example, the phase control unit 680 divides the reference frequency signal FR into the first plurality of frequency signals FRD0, FRD90, FRD180, and FRD270 having the same phase differences with respect to one another, divides each of the division frequency signals FD1, FD2, FD3 and FD4 into the second plurality of frequency signals FD1D0, FD1D90, FD1D180, and FD1D270, FD2D0, FD2D90, FD2D180, and FD2D270, FD3D0, FD3D90, FD3D180, and FD3D270 and FD4D0, FD4D90, FD4D180, and FD4D270, and generates the frequency signals FD1D0, FD2D90, FD3D180 and FD4D270 each respectively having the same phase as the first frequency signals FRD0, FRD90, FRD180 and FRD270 as the phase division frequency signals FDC1, FDC2, FDC3 and FDC4.

In FIG. 12, a phase difference of 90 degrees corresponds to a delay of T (one period)/4. Accordingly, each up signal UP and down signal DN from the phase detectors PFD1, PFD2, PFD3 and PFD4 has delay of T/4 with respect to one another. Therefore, each of the current pulse signals ICP1˜ICP4 (e.g., N is four in FIG. 1) from each of the charge pumps Cp1˜CP4 has delay of T/4 with respect to one another, and the current pulse signals ICP1˜ICP4 do not overlap with respect to one another. Therefore, when the current signal ICP is input to the loop filter 630, a high-frequency component of the current signal ICP may be almost completely removed. Therefore, the control voltage VC (i.e., the output of the loop filter 630) may have no ripples. Accordingly, spurs may not be generated, thereby reducing the sigma-delta modulation noise.

For example, in FIG. 1, the spurs may be prevented by delaying the output of the multiple charge pump 140 using the second delay unit 130, and in FIG. 11, the spurs may be prevented by delaying the input of the multiple charge pump 620 using the phase control unit 680.

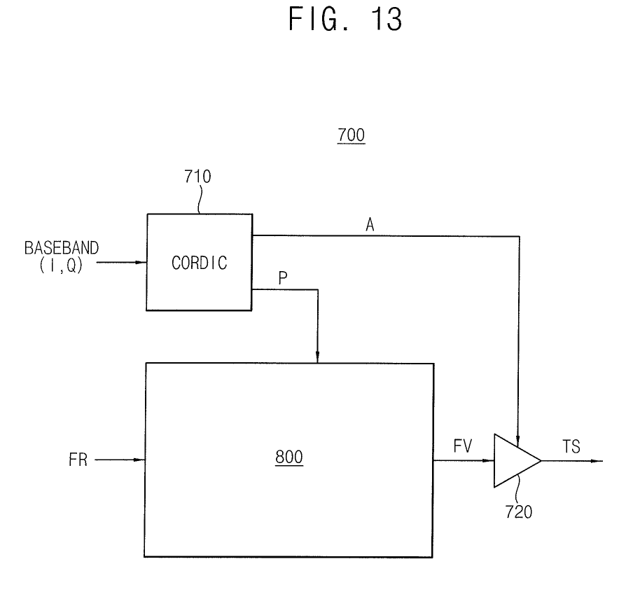

FIG. 13 is a block diagram illustrating an application circuit incorporating a frequency synthesizer according to an exemplary embodiment of the inventive concept. Referring to FIG. 13, an application circuit 700 includes a data processing unit 710, a frequency synthesizer 800 and a power amplifier 720.

The data processing unit 710 processes baseband data BASEBAND including an in-phase signal I and a quadrature signal Q to convert the processed baseband data BASEBAND to an amplitude signal A and a phase signal P. The frequency synthesizer 800 generates an oscillation frequency signal FV based on a reference frequency signal FR and the phase signal P. The power amplifier 720 synthesizes the oscillation frequency signal FV and the amplitude signal A to output a transmission signal TS.

The data processing unit 710 may be implemented with a Coordinate Rotational Digital Computer (CORDIC). The data processing unit 710 may convert the baseband data BASEBAND represented as coordinate components on the I-signal axis and the Q-signal axis to the amplitude component (i.e., the amplitude signal A) and the phase component (i.e., the phase signal P). The frequency synthesizer 800 generates the oscillation frequency signal FV based on the phase signal P. The power amplifier 720 receives the oscillation frequency signal FV and generates the transmission signal TS having output levels according to the amplitude signal A.

The application circuit 700 of FIG. 13 may employ the frequency synthesizer 10 of FIG. 1 or the frequency synthesizer 600 of FIG. 11. When the frequency synthesizer 10 or 600 of FIG. 1 or FIG. 11 is employed by the application circuit 700 of FIG. 13, the application circuit 700 of FIG. 13 may referred to as a polar transmitter.

In polar modulation, when a baseband bandwidth is greater than the loop bandwidth of a PLL, signal components exceeding the loop bandwidth may be lost. However, when the PLL loop bandwidth is broadened to prevent component loss, sigma-delta noise increases, and thus, the transmission signal includes more noise components.

However, the application circuit 700 of FIG. 13 incorporating the frequency synthesizer 10 of FIG. 1 or the frequency synthesizer 600 of FIG. 11 may reduce sigma-delta noise by preventing the spurs. Therefore, the transmission signal TS may be generated without component loss by broadening the PLL loop bandwidth when the baseband bandwidth is relatively broad, such as in wideband Code Division Multiple Access (WCDMA).

According to at least one embodiment of the inventive concept, the spurs may be prevented by delaying the inputs or the outputs of the multiple charge pump included in the frequency synthesizer with different delays with respect to one another. Therefore, at least exemplary embodiment of the inventive concept may be applied where wide bandwidths of the baseband data are required (e.g., direct phase modulation).

Having described exemplary embodiments of the inventive concept, it should be understood that various changes, substitutions and alterations can be made therein without departing from the scope of the present inventive concept. Accordingly, all such modifications are intended to be included within the scope of the disclosure.

What is claimed is:

1. A frequency synthesizer comprising:
a distributed phase detector circuit configured to delay an up signal and a down signal to generate a delayed up signal and a delayed down signal, wherein the up signal and the down signal are based on a reference frequency signal and each of a plurality of division frequency signals, and wherein the up signal and the down signal each include a plurality of bits;
a multiple charge pump configured to generate a distributed current signal including a plurality of current pulse signals, wherein each current pulse signal is based on each bit of the delayed up signal and the delayed down signal;
a loop filter configured to filter the distributed current signal to generate a control voltage;
a voltage-controlled oscillator configured to generate an oscillation frequency signal based on the control voltage; and
a dividing circuit configured to divide the oscillation frequency signal to generate the plurality of division frequency signals in response to a plurality of control signals.

2. The frequency synthesizer of claim 1, further comprising:
a sigma-delta modulator (SDM) configured to operate in synchronization with one of the plurality of division frequency signals, and sigma-delta modulate a clock signal and data to generate a modulation signal; and
a first delay unit configured to delay the modulation signal to generate the control signals for output to the dividing circuit.

3. The frequency synthesizer of claim 1, wherein the distributed phase detector circuit comprises:
a multiple phase detector that generates the up signal and the down signal based on respective frequency differences between the reference frequency signal and each of the plurality of division frequency signals; and
a second delay unit that delays each bit of the up signal the down signal by different delays with respect to one another to generate the delayed up signal and the delayed down signal.

4. The frequency synthesizer of claim 3, wherein the second delay unit includes a plurality of delay cells and each of the cells delays each bit of the up signal and the down signal by different delays with respect to one another in one period of the reference frequency signal.

5. The frequency synthesizer of claim 4, wherein each of the different delays increases as time elapses in one period of the reference frequency signal.

6. The frequency synthesizer of claim 4, wherein each of the different delays decreases as time elapses in one period of the reference frequency signal.

7. The frequency synthesizer of claim 1, wherein the dividing circuit includes:
a prescaler configured to generate a plurality of intermediate frequency signals having a same phase difference with respect to one another in response to the oscillation frequency signal; and
a plurality of modulus dividers commonly coupled to the prescaler and configured to respectively divide the plurality of intermediate frequency signals by respective ratios to generate the plurality of division frequency signals in response to the control signals.

8. The frequency synthesizer of claim 7, wherein each one of the plurality of modulus dividers includes:
a phase selection unit configured to select one of the plurality of intermediate frequency signals to generate a selection frequency signal in response to a phase control signal;
a first divider configured to divide the selection frequency signal with a fixed first division ratio to generate a divided selection frequency signal;
a counting unit configured to count the divided selection frequency signal to generate the division frequency signal and divide a counting interval of the divided selection frequency signal to generate a modulus control signal; and
a logic gate configured to generate the phase control signal based on the modulus control signal and the divided selection frequency signal.

9. The frequency synthesizer of claim 8, wherein the phase selection unit comprises:
a phase controller configured to generate a frequency control signal in response to the phase selection signal; and
a phase switch configured to switch and select one of the plurality of intermediate frequency signals in response to the frequency selection signal.

10. The frequency synthesizer of claim 8, wherein the counting unit comprises:
a main counter configured to count the divided selection frequency signal to generate a counting result as the division frequency signal in response to the control signal; and
a swallow counter configured to divide a counting interval of the divided selection frequency signal and count the counting interval with different counting coefficients to generate the modulus control signal, wherein the swallow counter is reset by the division frequency signal.

11. The frequency synthesizer of claim 2, wherein the SDM is one of fourth-order or fifth-order.

12. The frequency synthesizer of claim 11, wherein the fourth-order SDM comprises:
first, second, third, and fourth delayers;
first, second, third, fourth, fifth, and sixth adders;
first, second, third, and fourth feedback coefficient multipliers; and
a quantizer,
wherein the first adder, second adder, first delayer, third adder, second delayer, fourth adder, third delayer, fifth adder, fourth delayer, fourth feedback coefficient multiplier, sixth adder, and quantizer are respectively and consecutively connected in series,
wherein the first adder adds the corresponding one division frequency signal to an output of the quantizer,
wherein the second adder adds an output of the first adder to an output of the first feedback coefficient multiplier,
wherein the third adder adds an output of the first delayer and an output of the second feedback coefficient multiplier,
wherein the fourth adder adds an output of the second delayer and an output of the third feedback coefficient multiplier,
wherein the fifth adder adds an output of the third delayer and an output of the fourth feedback coefficient multiplier, and
wherein the sixth adder adds others outputs of the first, second, third, and fourth feedback coefficient multipliers.

13. The frequency synthesizer of claim 12, wherein the first, second, third, and fourth feedback coefficient multipliers respectively have coefficients of 3, 3.5, 2, and 0.5.

14. The frequency synthesizer of claim 11, wherein the fifth-order SDM comprises:
first, second, third, fourth, and fifth delayers;
first, second, third, fourth, fifth, sixth, and seventh adders;
first, second, third, fourth, and fifth feedback coefficient multipliers; and
a quantizer,
wherein the first adder, second adder, first delayer, third adder, second delayer, fourth adder, third delayer, fifth adder, fourth delayer, sixth adder, fifth delayer, fifth feedback coefficient multiplier, seventh adder, and quantizer are respectively and consecutively connected in series,
wherein the first adder adds the corresponding one division frequency signal to an output of the quantizer,
wherein the second adder adds an output of the first adder to an output of the first feedback coefficient multiplier,
wherein the third adder adds an output of the first delayer and an output of the second feedback coefficient multiplier,
wherein the fourth adder adds an output of the second delayer and an output of the third feedback coefficient multiplier,
wherein the fifth adder adds an output of the third delayer and an output of the fourth feedback coefficient multiplier,
wherein the sixth adder adds an output of the fourth delayer and an output of the fifth feedback coefficient multiplier, and
wherein the seventh adder adds others outputs of the first, second, third, fourth feedback, and fifth feedback coefficient multipliers.

15. The frequency synthesizer of claim 14, wherein the first, second, third, fourth, and fifth feedback coefficient multipliers respectively have coefficients of 4, 6.5, 5.5, 2.5, and 0.5.

16. A frequency synthesizer comprising:
a multiple phase detector configured to generate an up signal and a down signal in response to a reference frequency signal and each of a plurality of phase division frequency signals, wherein the up signal and the down signal each have a plurality of bits;
a multiple charge pump configured to generate a current signal including a plurality of current pulse signals, wherein each current pulse signal is based on each bit of the up signal and the down signal;
a loop filter configured to filter the current signal to generate a control voltage;
a voltage-controlled oscillator configured to generate an oscillation frequency signal based on the control voltage;
a dividing circuit configured to divide the oscillation frequency signal to generate the plurality of division frequency signals in response to a plurality of control signals; and
a phase control unit configured to divide the reference frequency signal into a first plurality of frequency signals having a same phase difference with respect to one another, to divide each of the division frequency signals into a second plurality of frequency signals to generate in-phase frequency signals as the phase division frequency signals,
wherein each of the in-phase frequency signals have the same phase as one each of the first plurality of frequency signals and one of the second plurality of frequency signals.

17. The frequency synthesizer of claim 16, wherein the phase control unit includes:
a first divider that generates the first plurality of frequency signals based on the reference frequency signal; and
a second plurality of dividers that generates the second plurality of frequency signals based on the division frequency signals.

18. The frequency synthesizer of claim 16, wherein the multiple phase detector includes a plurality of phase detectors, each of the phase detectors detecting a phase difference between each of the first plurality of frequency signals and each of the plurality of phase division frequency signals.

19. A polar transmitter comprising:
a data processing unit configured to process baseband data and convert the processed baseband data to an amplitude signal and a phase signal;
a frequency synthesizer configured to generate an oscillation frequency signal based on a reference frequency signal and the phase signal; and
a power amplifier configured to synthesize the oscillation frequency signal and the amplitude signal to output a transmission signal,
wherein the frequency synthesizer generates the oscillation frequency signal based on the reference frequency signal and each of a plurality of division frequency signals, and the frequency synthesizer includes a distributed phase detector circuit that distributes an up signal and a down signal to prevent the up signal and the down signal from overlapping one another,
wherein the up signal and the down signal are based on respective phase differences between the reference frequency signal and each of the plurality of division frequency signals.

20. The polar transmitter of claim 19, wherein the data processing unit is a Coordinate Rotational Digital Computer (CORDIC).
